(19) United States
(12) Patent Application Publication
(10) Pub. No.: US 2026/0033402 A1
(43) Pub. Date: Jan. 29, 2026

(54) QUANTUM DEVICE AND METHOD FOR MANUFACTURING QUANTUM DEVICE

(71) Applicant: NEC Corporation, Tokyo (JP)

(72) Inventor: Kunihiko ISHIHARA, Tokyo (JP)

(73) Assignee: NEC Corporation, Tokyo (JP)

(21) Appl. No.: 19/262,390

(22) Filed: Jul. 8, 2025

(30) Foreign Application Priority Data
Jul. 25, 2024 (JP) 2024-119605

(51) Int. Cl. H01L 23/498; H01L 21/52; H01L 23/00; H01L 23/427

(52) U.S. Cl. CPC H01L 23/49833; H01L 23/427; H01L 23/49838; H01L 24/16; H01L 21/52; H01L 2224/16227

(57) ABSTRACT

A quantum device includes a quantum chip, an interposer including a first wiring layer over which the quantum chip is mounted, a socket disposed to face the first wiring layer and including a plurality of terminals, and a board having a second wiring layer facing the first wiring layer. Each of the plurality of terminals electrically connects the first wiring layer and the second wiring layer, the socket includes a recessed unit housing the quantum chip, and the recessed unit has a first metal surface covering at least a part of the quantum chip.

This application is based upon and claims the benefit of priority from Japanese patent application No. 2024-119605, filed on Jul. 25, 2024, the disclosure of which is incorporated herein in its entirety by reference.

### TECHNICAL FIELD

The present disclosure relates to a quantum device and a method for manufacturing a quantum device.

### BACKGROUND ART

A quantum device including a qubit circuit has been known.

For example, in JP 2022-002234 A, “a quantum device including: a quantum chip; an interposer on which the quantum chip is mounted; and a socket disposed so as to be opposite to the interposer, the socket including a movable pin and a housing supporting the movable pin, in which at least one end of the movable pin, which includes the one end and the other end opposite to the one end, is movable relative to the housing, the one end being in electrical contact with a terminal of the interposer, and the other end is in an electrical contact with a terminal of a board on which a connector is formed, the connector being configured to serve as external input and output” is disclosed.

The interposer in a fifth example embodiment disclosed in JP 2022-002234 A has a mounting surface on which the quantum chip is mounted and an opposite surface opposite to the mounting surface, and the socket is mounted on the mounting surface.

### SUMMARY

In the quantum device described in the fifth example embodiment disclosed in JP 2022-002234 A, electromagnetic noise may be applied to a qubit circuit.

An object of the present disclosure is to provide a quantum device and a method for manufacturing a quantum device for solving the above-described problem.

A quantum device of the present disclosure includes a quantum chip, an interposer including a first wiring layer over which the quantum chip is mounted, a socket disposed to face the first wiring layer and including a plurality of terminals, and a board having a second wiring layer facing the first wiring layer, in which each of the plurality of terminals electrically connects the first wiring layer and the second wiring layer, the socket includes a recessed unit housing the quantum chip, and the recessed unit has a first metal surface covering at least a part of the quantum chip.

A method for manufacturing a quantum device of the present disclosure includes mounting a quantum chip over a first wiring layer of an interposer, and disposing a socket including a plurality of terminals to face the first wiring layer, in which in the disposing, a board having a second wiring layer is disposed to face the first wiring layer, in the disposing, each of the plurality of terminals electrically connects the first wiring layer and the second wiring layer, the socket includes a recessed unit housing the quantum chip, and the recessed unit has a first metal surface covering at least a part of the quantum chip.

According to the quantum device and the method for manufacturing a quantum device according to the present disclosure, electromagnetic noise is less likely to be applied to the qubit circuit.

### BRIEF DESCRIPTION OF THE DRAWINGS

Exemplary features and advantages of the present disclosure will become apparent from the following detailed description when taken with the accompanying drawings in which:

FIG. 1 is a cross-sectional view I illustrating an example of a configuration of a quantum device according to the present disclosure;

FIG. 2 is a flowchart I illustrating an example of processing of a method for manufacturing a quantum device according to the present disclosure;

FIG. 3 is a cross-sectional view I illustrating an example of a configuration of the quantum device according to a modification;

FIG. 4 is a cross-sectional view II illustrating an example of a configuration of the quantum device according to a modification;

FIG. 5 is a bottom view in an example of a configuration of the quantum device according to a modification;

FIG. 6 is a cross-sectional view II illustrating an example of a configuration of a quantum device according to the present disclosure; and

FIG. 7 is a flowchart II illustrating an example of processing of the method for manufacturing a quantum device according to the present disclosure.

### EXAMPLE EMBODIMENT

Hereinafter, examples of example embodiments according to the present disclosure will be described with reference to the drawings. The drawings and specific configurations employed in the example embodiments are not intended to be used for the interpretation of the disclosure. In all the drawings, the same or corresponding components are denoted by the same reference numerals, and the common description will not be repeated.

In the present disclosure, the drawings are associated with one or more example embodiments.

### First Example Embodiment

Hereinafter, example embodiments according to the present disclosure will be described with reference to the drawings.

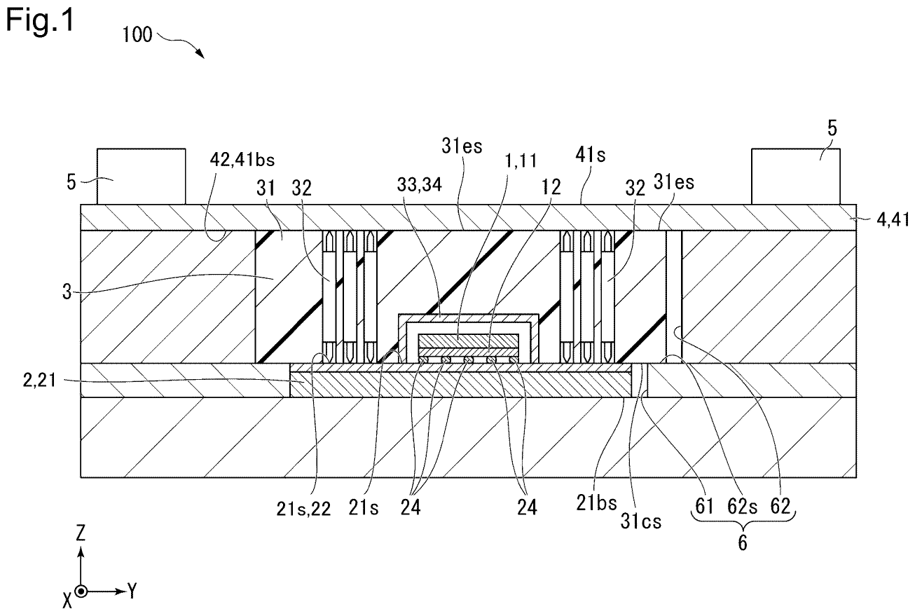

Hereinafter, an example of a configuration of a quantum device in the present disclosure will be described with reference to FIG. 1.

Hereinafter, a direction in which a front surface 21s of a base material 21 included in an interposer 2 faces is defined as a Z direction. A direction along the front surface 21s and intersecting the Z direction is defined as an X direction. A direction intersecting the Z direction and the X direction is defined as a Y direction. One direction along the X direction is defined as a +X direction, and the opposite direction along the X direction is defined as a −X direction. One direction along the Y direction is defined as a +Y direction, and the opposite direction along the Y direction is defined as a −Y direction. One direction along the Z direction is defined as a +Z direction, and the opposite direction along the Z direction is defined as a −Z direction.

### (Configuration of Quantum Device)

As illustrated in FIG. 1, a quantum device 100 includes a quantum chip 1, an interposer 2, a socket 3, a board 4, connectors 5, and a cooling unit 6.

This quantum device 100 has a basic configuration in which the quantum chip 1 is connected to the board 4 via the interposer 2, and terminals 32 is used for connecting the interposer 2 and the board 4. The cooling unit 6 houses the quantum chip 1 and the interposer 2, and maintains an ultralow temperature that enables achievement of the quantum state.

### (Configuration of Quantum Chip)

The quantum chip 1 includes a base material 11 and a connection unit 12. The connection unit 12 is not necessarily required to be a conductor wiring layer that forms a circuit pattern as long as it is a conductor that can be connected to a circuit element in the quantum chip 1.

The wiring layer (connection unit 12) of the quantum chip 1 is mounted over the interposer 2 with bumps 24 interposed therebetween. Therefore, the quantum chip 1 is flip-chip mounted over the interposer 2. The connection unit 12 preferably contains a superconducting material.

More specifically, the base material 11 is formed using a material that is less deformed in a superconducting environment, such as silicon (Si), gallium arsenide (GaAs), sapphire, or glass. The connection unit 12 constituting a qubit circuit formed on the base material 11 is niobium nitrides such as niobium (Nb) or niobium nitride, aluminum (Al), indium (In), lead (Pb), tin (Sn), rhenium (Re), palladium (Pd), titanium (Ti), titanium nitrides, tantalum (Ta), tantalum nitrides, or an alloy having superconductivity and containing at least one of these.

### (Configuration of Interposer)

The interposer 2 includes the base material 21, a first wiring layer 22, and at least one or more bumps 24.

The first wiring layer 22 is provided on the front surface 21s of the base material 21. The entirety of a back surface 21bs of the base material 21 is in contact with the cooling unit 6. In this case, the interposer 2 may be disposed with a space interposed between the interposer 2 and the inner surface of a recessed unit 61 included in the cooling unit 6. With such a configuration, it is possible to minimize stress and strain due to a difference in shrinkage between the interposer 2 and the cooling unit 6, caused by a temperature change to a cryogenic temperature. The interposer 2 may be disposed in such a way as to abut on a part of the inner surface of the recessed unit 61. When the interposer 2 abuts, the movement of the interposer 2 is restrained in the Y direction.

Similarly to the quantum chip 1, the base material 21 is formed using a material that is less deformed in a superconducting environment, such as silicon (Si), gallium arsenide (GaAs), sapphire, or glass.

The first wiring layer 22 contains niobium nitrides such as niobium (Nb) or niobium nitride, aluminum (Al), indium (In), lead (Pb), tin (Sn), rhenium (Re), palladium (Pd), titanium (Ti), titanium nitrides, tantalum (Ta), tantalum nitrides, or an alloy having superconductivity and containing at least one of these.

A metal layer containing gold (Au), platinum (Pt), palladium (Pd), or the like may be formed on a surface of the first wiring layer 22. For example, a metal layer containing gold (Au), platinum (Pt), palladium (Pd), or the like may be formed on the surface of the first wiring layer 22 in a region outside a cavity resonator described later.

The interposer 2 may include a through-via (TV). The TV is used to acquire the ground potential from the cooling unit 6.

Each bump 24 may contain the same superconducting material as the connection unit 12 or may contain a superconducting material different from the connection unit 12. In a case where the bumps 24 include a plurality of metal layers, at least one layer preferably contains a superconducting material.

### (Configuration of Socket)

The socket 3 includes a housing 31, two or more terminals 32, a recessed unit 33, and a first metal unit 34. The socket 3 has a hole through which a fastener such as a screw can be inserted on a contact surface with the board 4.

The socket 3 has a facing surface 31cs and another end surface 31es in the Z direction. For example, in the present example embodiment, the facing surface 31cs faces the −Z direction, and the other end surface 31es faces the +Z direction.

The socket 3 is disposed to face the first wiring layer 22 of the interposer 2. For example, in the present example embodiment, the socket 3 is disposed in such a way that the facing surface 31cs is disposed to face the first wiring layer 22.

The socket 3 includes a recessed unit 33 housing the quantum chip 1. In the present example embodiment, since the socket 3 is placed on the interposer 2, the quantum chip 1 is housed in a space formed by the recessed unit 33 and the interposer 2.

The inner surface of the recessed unit 33 is covered with the first metal unit 34. The first metal unit 34 is formed by including a metal surface consisting of gold (Au), platinum (Pt), palladium (Pd), or the like. The metal surface of the first metal unit 34 may be exposed to the outside, or the first metal unit 34 may be covered with the metal surface and then exposed to the outside. That is, the first metal unit 34 may be a thin film or may be layer-shaped. For example, in the present example embodiment, a metal surface (first metal surface) is formed on a surface of the first metal unit 34. The metal surface (first metal surface) is formed by means such as sputtering, vapor deposition, electroless plating, or electrolytic plating.

In this way, the quantum chip 1 is surrounded by the metal surface (first metal surface) of the first metal unit 34 and the first wiring layer 22 containing an alloy having superconductivity. In this case, a gap is formed between the quantum chip 1 and the recessed unit 33. A cavity resonator including the metal surface (first metal surface) of the first metal unit 34 and the first wiring layer 22 is obtained. The cavity resonator has the above-described gap. As the gap is reduced, the resonance mode of the cavity resonator shifts to a high frequency band. Since the resonance mode generated in the quantum chip is about 5 GHz to 10 GHz, electromagnetic noise is less likely to be applied to the qubit circuit when the resonance mode shifts to a frequency band higher than this frequency band (for example, 20 GHz to 30 GHz) by the reduction of the gap.

The housing 31 preferably contains an insulating material. At least a portion of the housing 31 in contact with the terminals 32 contains an insulating material. The housing 31 also preferably contains a non-magnetic material. The housing 31 preferably further contains a material whose thermal expansion coefficient is equivalent to the thermal expansion coefficient of the interposer 2.

The housing 31 may contain quartz or plastic, such as engineering plastic. The housing 31 may also contain a composite material with low linear expansion coefficient including aluminum oxide (also referred to as Al₂O₃ or alumina), a mica-based machinable ceramic, aluminum nitride (AlN), zirconia (ZrO₂), a macol-based machinable ceramic, glass, a resin, and a silica filler. The housing 31 may also contain a superconducting material as long as insulation is ensured between the housing 31 and the terminals 32.

A plurality of terminals 32 made of conductors penetrate the housing 31.

In the present example embodiment, it is assumed that the dimension of the socket 3 in the X direction is larger than the dimension of the interposer 2 in the X direction.

One end of a terminal 32 is in contact with the first wiring layer 22, and the other end of the terminal 32 is in contact with the second wiring layer 42; thereby, the first wiring layer 22 and the second wiring layer 42 are electrically connected to each other. In this case, the interposer 2 and the board 4 are electrically connected to each other. Furthermore, the second wiring layer 42 is connected to the connectors 5, and constitutes a circuit extending from the interposer 2 to the connectors 5 via the first wiring layer 22 to the terminals 32 to the second wiring layer 42.

### (Configuration of Terminal)

The terminal 32 is a pin. The pin is expandable and contractible in the longitudinal direction. One end of the pin extends in the −Z direction, and the other end of the pin extends in the +Z direction. The pin includes a compression spring, and one end or the other end of the terminal 32 is biased in the Z direction by the compression spring being elastically deformed in the Z direction.

Since the one end or the other end of the terminal 32 is biased in the Z direction, the one end of the terminal 32 can be electrically connected while being in close contact with the first wiring layer 22. Since the one end or the other end of the terminal 32 is biased in the Z direction, the other end of the terminal 32 can be electrically connected while being in close contact with the second wiring layer 42. In this case, a large contact area can be secured along with the plastic deformation of a metal constituting the first wiring layer 22 and/or second wiring layer 42, and the terminal 32 can be brought into close contact by the stress generated in the elastically deformed first wiring layer 22 and/or second wiring layer 42. Accordingly, reliability of electrical connection between the terminal 32 and the first wiring layer 22 can be increased between the interposer 2 and the board 4. Reliability of electrical connection between the terminal 32 and the second wiring layer 42 can be increased between the interposer 2 and the board 4.

The terminal 32 may contain a superconducting material. For example, the terminal 32 may contain the same superconducting material as the connection unit 12 and the like, or may contain a superconducting material different from the first wiring layer 22 and the like. The terminal 32 may also contain the same normal conducting material as the metal layer formed on the surface of the first wiring layer 22, or may contain a normal conducting material different from the first wiring layer 22. This metal layer is formed on the surface of the first wiring layer 22 as necessary within the region outside the cavity resonator as described above. The terminal 32 preferably contains a non-magnetic material. The terminal 32 preferably contains, for example, a palladium alloy, a gold alloy, beryllium copper (BeCu), gold (plated finish), niobium (Nb), niobium titanium (Nb—Ti), or titanium (Ti).

### (Configuration of Board)

The board 4 is disposed to face the first wiring layer 22.

The board 4 includes a base material 41 and the second wiring layer 42.

For example, in the present example embodiment, the base material 41 is plate-shaped, and the base material 41 has an upper surface 41s and a lower surface 41bs in the Z direction. The lower surface 41bs is provided with the second wiring layer 42 facing the first wiring layer 22. The connectors 5 connectable to an external device are provided on the upper surface 41s. The lower surface 41bs faces the other end surface 31es of the socket 3.

The base material 41 has a plurality of bearing surfaces for supporting fasteners such as screws on the upper surface 41s, and each bearing surface is provided with a through-hole. The board 4 is coupled to the socket 3 with a fastener such as a screw. The board 4 is coupled to the cooling unit 6 with a fastener such as a screw.

The base material 41 may contain, as a material, epoxy, acrylic, urethane, polyimide, phenol, a liquid crystal polymer, or the like, and may further contain silica, an organic resin, a ceramic filler, or glass fiber in addition to such a material. The base material 41 may contain a solidified ceramic powder.

The second wiring layer 42 provided on the lower surface 41bs contains, for example, a material such as copper (Cu) or aluminum (Al), and is formed in a predetermined circuit pattern by means such as sputtering, vapor deposition, electroless plating, or electrolytic plating. As a specific method for forming a layer containing a conductive material into the predetermined circuit pattern, a subtractive method using a resist applied to the surface as a mask, an additive method using plating, a SEMI additive method, a lift-off method in which the applied resist is removed to form a pattern, or the like can be applied.

### (Configuration of Connector)

The connectors 5 are used to exchange input and output with an external device. For example, the external device inputs and outputs power, signals, and the like to and from the quantum chip 1 via the socket 3.

The connectors 5 can be electrically connected to the second wiring layer 42.

### (Configuration of Cooling Unit)

The cooling unit 6 has a cooling function. Examples of the cooling unit 6 include a stage. The stage is a so-called cold stage including a cryogenic refrigerator (not illustrated) of about milliKelvin [mK] capable of achieving a superconducting state in the materials constituting the quantum chip 1 and the interposer 2.

The cooling unit 6 includes the recessed unit 61 and a counterbore 62. The cooling unit 6 also has a hole through which a fastener such as a screw can be inserted on a contact surface with the board 4.

The recessed unit 61 is open in the +Z direction and has a shape corresponding to the planar shape of the interposer 2 in the XY plane. The counterbore 62 is formed around an opening portion of the recessed unit 61 and has a shape corresponding to the planar shape of the socket 3 in the XY plane. In this case, a stepped surface 62s having a step with the bottom of the recessed unit 61 is formed around the opening portion of the recessed unit 61.

The interposer 2 is disposed at the bottom of the recessed unit 61.

The stepped surface 62s is, for example, parallel to the front surface 21s of the base material 21. The stepped surface 62s is formed around the recessed unit 61. The stepped surface 62s surrounds the recessed unit 61.

The position of the stepped surface 62s in the +Z direction is substantially the same level position as the front surface 21s or a position higher than the front surface 21s. For example, in the present example embodiment, the position of the stepped surface 62s in the +Z direction is substantially the same level position as the front surface 21s. As a result, a part of the facing surface 31cs of the socket 3 can be in contact with the stepped surface 62s. In this case, the socket 3 may be disposed with a space interposed between the socket 3 and the inner surface of the counterbore 62 of the cooling unit 6. With such a configuration, it is possible to minimize stress and strain due to a difference in shrinkage between the socket 3 and the cooling unit 6, caused by a temperature change to a cryogenic temperature. The socket 3 may be disposed in such a way as to abut on a part of the inner surface of the counterbore 62. When the socket 3 abuts, the movement of the socket 3 is restrained in the Y direction. In a case where the interposer 2 is disposed in such a way as to abut on a part of the inner surface of the recessed unit 61 when the socket 3 abuts, the following advantages are obtained. The relative positional relationship in the Y direction between the quantum chip 1 and the socket 3 disposed inside the cooling unit 6 is less likely to deviate by restraining the movement of the interposer 2 and the socket 3 in the Y direction.

The cooling unit 6 desirably contains, for example, a metal such as copper (Cu) or a copper alloy. For example, a cooling capacity capable of achieving the ultralow temperature exemplified above is required for the cooling unit 6 because in a case where niobium (Nb) is contained as the superconducting material of the quantum chip 1, a superconducting phenomenon at an ultralow temperature of equal to or less than 9.2 Kelvin [K] is used, and in a case where aluminum (Al) is contained, a superconducting phenomenon at an ultralow temperature of equal to or less than 1.2 Kelvin [K] is used.

At least one of the interposer 2 or the socket 3 is in contact with the cooling unit 6 having a cooling function. For example, in the present example embodiment, the back surface 21bs of the interposer 2 and a part of the facing surface 31cs of the socket 3 are in contact with the cooling unit 6.

When at least a part of the interposer 2 is in contact with the cooling unit 6, the interposer 2 functions as a heat transfer path, and the qubit circuit included in the quantum chip 1 is cooled to a cryogenic temperature.

In this way, the superconducting phenomenon can be utilized. In this case, in a case where the entirety of the back surface 21bs of the interposer 2 is in contact with the cooling unit 6, the amount of heat transfer increases more than when a part of the interposer 2 is in contact with the cooling unit 6. Therefore, the cooling efficiency of the interposer 2 is improved, and the quantum chip 1 is more efficiently cooled.

The ground potential of the interposer 2 may be acquired from the cooling unit 6. For example, the ground potential is acquired from the cooling unit 6 via the TV of the interposer 2. In this case, the metal layer of the socket 3 acquires the ground potential by contacting with the interposer 2.

### (Manufacturing Method)

A method for manufacturing a quantum device in the present example embodiment will be described.

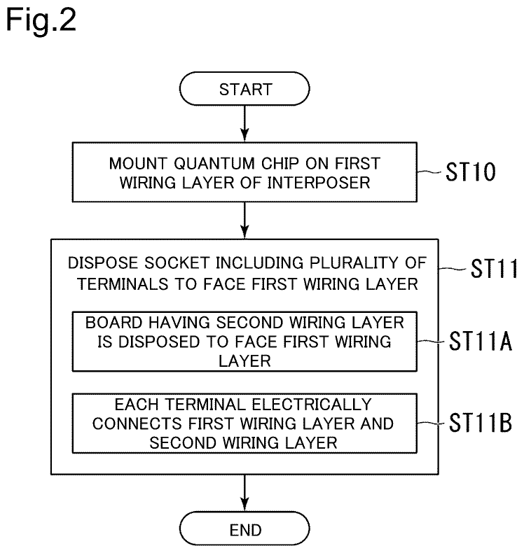

The method for manufacturing a quantum device in the present example embodiment is implemented according to the flow illustrated in FIG. 2.

First, a manufacturer mounts the quantum chip 1 on the first wiring layer 22 of the interposer 2 (step ST10: mounting step).

Next, the manufacturer disposes the socket including the plurality of terminals to face the first wiring layer 22 (step ST11: disposing step).

The socket 3 used in step ST11 includes the recessed unit 33 housing the quantum chip 1, and the recessed unit 33 has a first metal surface covering at least a part of the quantum chip 1. For example, the first metal unit 34 covering the inner surface of the recessed unit 33 may be provided. The first metal unit 34 is formed by including a metal surface consisting of gold (Au), platinum (Pt), palladium (Pd), or the like.

The metal surface of the first metal unit 34 may be exposed to the outside, or the first metal unit 34 may be covered with the metal surface (first metal surface) and then exposed to the outside. That is, the first metal unit 34 may be a thin film or may be layer-shaped.

The first metal surface may be a surface of a film such as a partially opened mesh film or porous film.

In step ST11, the board 4 having the second wiring layer 42 is disposed to face the first wiring layer 22 (step ST11A).

In step ST11, each terminal (terminal 32) electrically connects the first wiring layer 22 and the second wiring layer 42 (step ST11B).

Here, the quantum device 100 having the structure in which electromagnetic noise is less likely to be applied to the qubit circuit is manufactured (completed).

### (Operation and Effect)

According to the quantum device of the present disclosure, at least a part of the quantum chip 1 is covered with the metal surface (first metal surface) of the first metal unit 34. The quantum chip 1 covered with the metal surface (first metal surface) of the first metal unit 34 is subjected to electromagnetic shielding.

Therefore, in the quantum device according to the present disclosure, electromagnetic noise is less likely to be applied to the qubit circuit.

In the above-described disclosure, the first metal surface of the socket 3 has an electromagnetic shielding function for the quantum chip 1.

As a comparative example, in a case of a configuration in which the whole including the quantum chip to be shielded and the socket is covered with a cover having the first metal surface, a space where the cover having the first metal surface is provided is separately required. In a case where such a space is required, a space for wiring to an external device is limited. For example, due to such a space limitation, the number of terminals that exchange signals with an external device is limited.

In contrast, according to the quantum device 100 of the present disclosure, the first metal surface provided on the socket 3 covers at least a part of the quantum chip 1 to be shielded.

Therefore, according to the quantum device 100 of the present disclosure, the space for wiring to an external device is less likely to be limited as compared with the comparative example. For example, according to the quantum device 100 of the present disclosure, the number of terminals 32 that exchange signals with the external device is less likely to be limited as compared with the comparative example.

By adopting the quantum device 100 of the present disclosure “including the quantum chip 1, the interposer 2 including the first wiring layer 22 on which the quantum chip 1 is mounted, the socket 3 disposed to face the first wiring layer 22 and including the plurality of terminals, and the board 4 having the second wiring layer 42 facing the first wiring layer 22, in which each terminal (terminal 32) electrically connects the first wiring layer 22 and the second wiring layer 42, the socket 3 includes the recessed unit 33 housing the quantum chip 1, and the recessed unit 33 has the first metal surface covering at least a part of the quantum chip1”, the following effects can be obtained.

According to the quantum device 100 of the present disclosure, at least a part of the quantum chip 1 is covered with the metal surface (first metal surface) of the first metal unit 34.

As a result, it is possible to obtain an effect of “the quantum chip 1 covered with the metal surface (first metal surface) of the first metal unit 34 is subjected to electromagnetic shielding”. Therefore, in the quantum device according to the present disclosure, electromagnetic noise is less likely to be applied to the qubit circuit.

Furthermore, in the quantum device 100 of the present disclosure, by virtue of “the terminal 32 is a pin, and the pin is expandable and contractible in the longitudinal direction”, it is possible to obtain an effect of “since the pin is expandable and contractible in the longitudinal direction following the volume change of the terminals or the like generated when the quantum device 100 is cooled to a cryogenic temperature, disconnection of the first wiring layer 22 and/or the second wiring layer 42 in contact with the terminals 32 can be minimized”.

Furthermore, in the quantum device 100 of the present disclosure, since “the socket 3 is placed on the interposer 2”, the quantum chip 1 is housed in the space formed by the recessed unit 33 and the interposer 2. Since electromagnetic waves are less likely to enter between the socket 3 and the interposer 2, an effect of “electromagnetic noise is less likely to be applied to the qubit circuit” can be obtained.

Furthermore, in the quantum device 100 of the present disclosure, by virtue of “at least one of the interposer 2 or the socket 3 is in contact with the cooling unit 6 having a cooling function”, it is also possible to obtain an effect of “the quantum chip 1 mounted on the interposer 2 is easily cooled”.

Furthermore, in an inspection apparatus of the present disclosure, by virtue of “the interposer 2 has the first wiring layer 22 on the front surface 21s, and the first wiring layer 22 contains an alloy having superconductivity”, the following effects can be obtained.

According to the quantum device 100 of the present disclosure, the quantum chip 1 is surrounded by the metal surface (first metal surface) of the first metal unit 34 and the first wiring layer 22 containing an alloy having superconductivity.

As a result, it is possible to obtain an effect of “the quantum chip 1 surrounded by the metal surface (first metal surface) of the first metal unit 34 and the first wiring layer 22 is further subjected to electromagnetic shielding”.

Furthermore, in the quantum device 100 of the present disclosure, by virtue of “the gap is provided between the quantum chip 1 and the recessed unit 33”, the following effects can be obtained.

In the cavity resonator obtained by the quantum chip 1 surrounded by the metal surface (first metal surface) of the first metal unit 34 and the first wiring layer 22 containing an alloy having superconductivity, the resonance mode shifts to a high frequency band as the gap is reduced. Therefore, it is possible to obtain an effect of “electromagnetic noise is less likely to be applied to the qubit circuit by reducing the gap to cause the resonance mode to shift to a high frequency band”.

### First Modification

For example, although the through-hole is provided in the bearing surface on the upper surface 41s, instead of the through hole, a protruding unit in which a part of the lower surface 41bs of the base material protrudes in the −Z direction may be provided in the base material 41.

The protruding unit can be fitted into a hole provided in each of the cooling unit 6 and the socket 3.

### Second Modification

The first metal surface may include a superconducting material. The superconducting material functions as magnetic shielding during cooling. Therefore, the quantum chip 1 surrounded by the metal surface (first metal surface) of the first metal unit 34 and the first wiring layer 22 containing an alloy having superconductivity is subjected to magnetic shielding in addition to the electromagnetic shielding. Therefore, electromagnetic noise is less likely to be applied to the qubit circuit.

### Third Modification

In the above-described disclosure, although the other end surface 31es of the socket 3 and the board 4 are in contact with each other, a space may be formed between the other end surface 31es and the interposer 2 as long as the other end of the terminal 32 can be in contact with the second wiring layer 42.

### Fourth Modification

In the above-described disclosure, although the facing surface 31cs of the socket 3 and the interposer 2 are in contact with each other, a space may be formed between the facing surface 31cs and the interposer 2 as long as the quantum chip 1 is surrounded by the metal surface (first metal surface) of the first metal unit 34 and the other metal surface.

### Fifth Modification

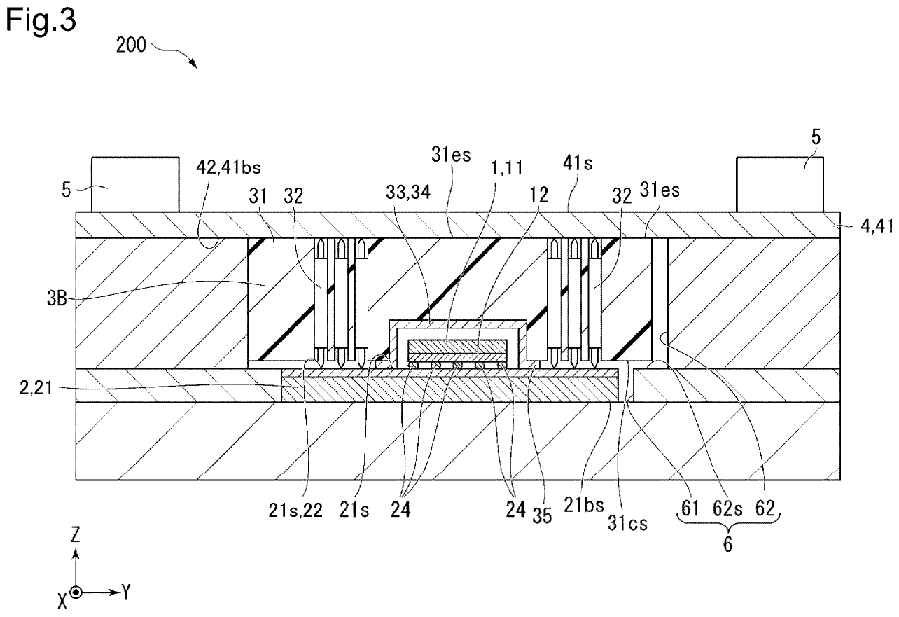

A quantum device 200 illustrated in FIG. 3 is similar to the above-described disclosure except for the points described below.

The quantum device 200 includes the quantum chip 1, the interposer 2, a socket 3B, the board 4, the connectors 5, and the cooling unit 6.

The socket 3B includes a housing 31, two or more terminals 32, a recessed unit 33, a first metal unit 34, and a connection unit 35.

The connection unit 35 connects the facing surface 31cs and the first metal surface.

The connection unit 35 is formed by including a metal surface consisting of gold (Au), platinum (Pt), palladium (Pd), or the like. The metal surface of the connection unit 35 may be exposed to the outside, or the connection unit 35 may be covered with the metal surface and then exposed to the outside. That is, the connection unit 35 may be a thin film or may be layer-shaped. For example, in the present modification, a metal surface (second metal surface) is formed on a surface of the connection unit 35. The metal surface (second metal surface) is formed by means such as sputtering, vapor deposition, electroless plating, or electrolytic plating.

At least one of the interposer 2 or the socket 3B is in contact with the cooling unit 6 having a cooling function. For example, in the present example embodiment, the entirety of the back surface 21bs of the interposer 2 is in contact with the cooling unit 6.

In the present modification, as compared with the quantum device 100 of the above-described disclosure, the electromagnetic wave is less likely to enter between the socket 3 and the interposer 2. In the quantum device 200 according to the present modification, electromagnetic noise is less likely to be applied to the qubit circuit.

The second metal surface may contain a superconducting material.

### Sixth Modification

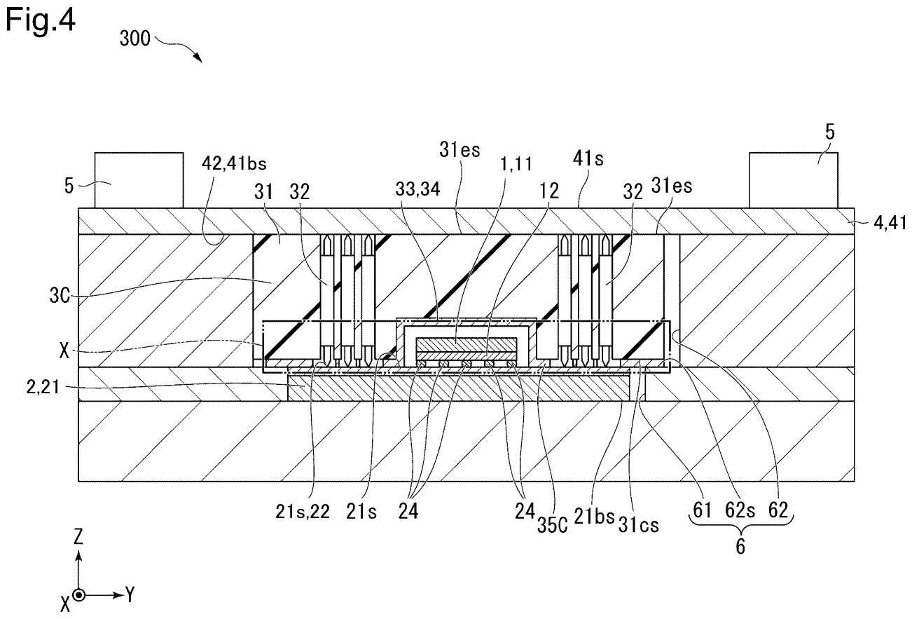

A quantum device 300 illustrated in FIG. 4 is similar to the above-described disclosure except for the points described below.

The quantum device 300 includes the quantum chip 1, the interposer 2, a socket 3C, the board 4, the connectors 5, and the cooling unit 6.

The socket 3C is different from the socket 3B in that the connection unit 35 covers the facing surface 31cs.

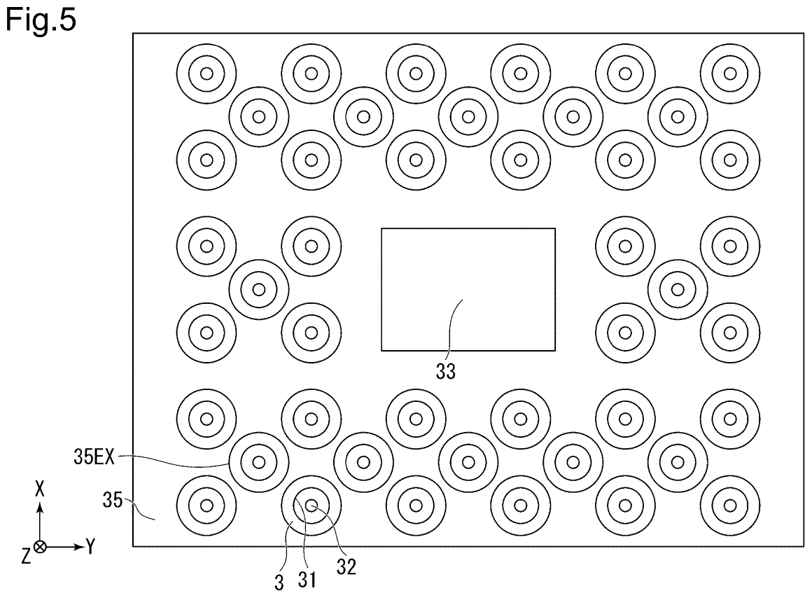

FIG. 5 is a view of the connection unit 35 as viewed from the −Z direction. The connection unit 35 has an opening 35EX in a portion overlapping with the terminal 32 in the Z direction. The opening 35EX includes a projection area of the terminal 32 projected in the Z direction and includes an opening larger than the projection area of the terminal 32. As a result, the electric field of a high frequency signal propagating through the terminal 32 is less likely to be inhibited.

The arrangement of the terminals 32 is merely an example, and is not limited thereto.

At least one of the interposer 2 or the socket 3 is in contact with the cooling unit 6 having a cooling function. For example, in the present example embodiment, the entirety of the back surface 21bs of the interposer 2 and a part of the connection unit 35 of the socket 3 are in contact with the cooling unit 6.

In the present modification, as compared with the quantum device 200 of the above-described disclosure, the electromagnetic wave is less likely to enter between the socket 3 and the interposer 2 because a large contact area between the connection unit 35 and the interposer 2 is secured. In the quantum device 300 according to the present modification, electromagnetic noise is less likely to be applied to the qubit circuit.

Since a part of the connection unit 35 covering the facing surface 31cs is in contact with the cooling unit 6 in a state where the facing surface 31cs of the socket 3 is covered with the metal surface (second metal surface), the cooling efficiency of the interposer 2 is easily improved, and the quantum chip 1 is more efficiently cooled.

### Seventh Modification

In the above-described disclosure, it has been described that the socket 3 and/or the interposer 2 is disposed in such a way as to abut on a part of the inside of the cooling unit 6 as means for restraining the movement of the socket 3 and/or the interposer 2 in the Y direction. However, in the present modification, the socket 3 and/or the interposer 2 may not directly abut on the inside of the cooling unit 6, but may instead abut on the inside of the cooling unit 6 via another member such as a spacer.

A method for making it difficult for the relative positional relationship in the Y direction between socket 3 and interposer 2 to deviate from each other by a positioning pin or the like, or other various methods may be adopted as means for restraining these movements in the Y direction.

### Second Example Embodiment

Hereinafter, example embodiments according to the present disclosure will be described with reference to the drawings.

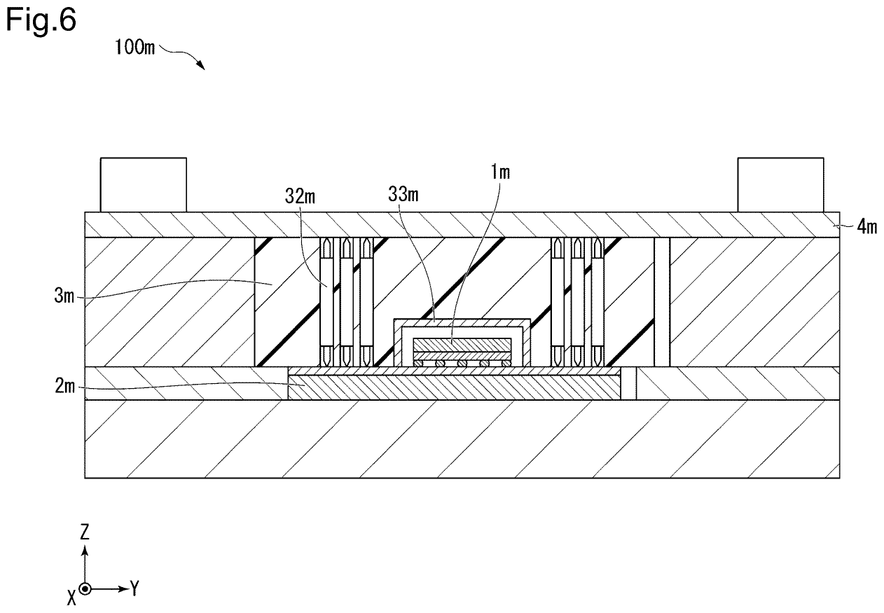

Hereinafter, an example of a configuration of a quantum device in the present disclosure will be described with reference to FIG. 6.

### (Configuration)

A quantum device 100m includes a quantum chip 1m, an interposer 2m including a first wiring layer on which the quantum chip 1m is mounted, a socket 3m disposed to face the first wiring layer and including a plurality of terminals, and a board 4m having a second wiring layer facing the first wiring layer, in which each terminal (terminal 32m) electrically connects the first wiring layer and the second wiring layer, the socket 3m includes a recessed unit 33m housing the quantum chip 1m, and the recessed unit 33m has a first metal surface covering at least a part of the quantum chip 1m.

### (Operation and Effect)

According to the quantum device of the present disclosure, at least a part of the quantum chip 1m is covered with the first metal surface. The quantum chip 1m covered with the first metal surface is subjected to electromagnetic shielding.

Therefore, in the quantum device according to the present disclosure, electromagnetic noise is less likely to be applied to the qubit circuit.

### Third Example Embodiment

Hereinafter, example embodiments according to the present disclosure will be described with reference to the drawings.

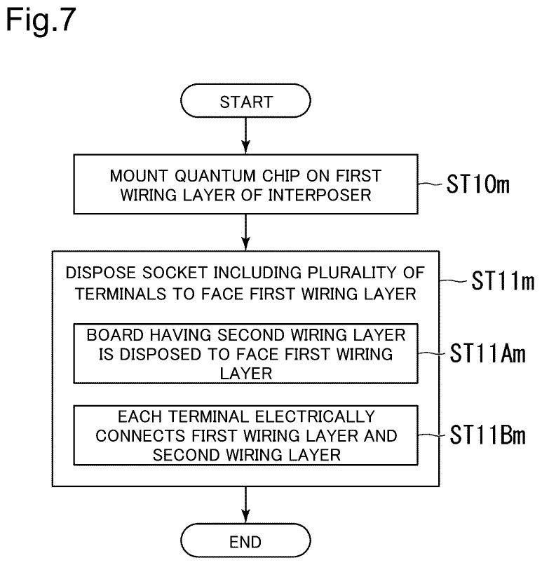

Hereinafter, an example of the method for manufacturing a quantum device in the present disclosure will be described with reference to FIG. 7.

The method for manufacturing a quantum device in the present disclosure is implemented according to the flow illustrated in FIG. 7.

The manufacturing of the quantum device includes a step of mounting a quantum chip over a first wiring layer of an interposer (step ST10m: mounting step), and a step of disposing a socket including a plurality of terminals to face the first wiring layer (step ST11m: disposing step). In the manufacturing of the quantum device, in the disposing step, a board having a second wiring layer is disposed to face the first wiring layer (step ST11Am), and in the disposing step, each terminal electrically connects the first wiring layer and the second wiring layer (step ST11Bm). In this case, the socket includes a recessed unit housing the quantum chip, and the recessed unit has a first metal surface covering at least a part of the quantum chip.

### (Operation and Effect)

According to the method for manufacturing a quantum device of the present disclosure, at least a part of the quantum chip is covered with the first metal surface. The quantum chip covered with the first metal surface is subjected to electromagnetic shielding.

Therefore, in the quantum device according to the present disclosure, electromagnetic noise is less likely to be applied to the qubit circuit.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. Each example embodiment can be appropriately combined with another example embodiment.

Some or all of the above-described example embodiments may be described as the following Supplementary Notes, but are not limited to the following Supplementary Notes.

### (Supplementary Note 1)

A quantum device including:
a quantum chip;
an interposer including a first wiring layer over which the quantum chip is mounted;
a socket disposed to face the first wiring layer and including a plurality of terminals; and
a board having a second wiring layer facing the first wiring layer, in which
each of the plurality of terminals electrically connects the first wiring layer and the second wiring layer,
the socket includes a recessed unit housing the quantum chip, and
the recessed unit has a first metal surface covering at least a part of the quantum chip.

### (Supplementary Note 2)

The quantum device according to Supplementary Note 1, in which
each of the plurality of terminals is a pin, and
the pin is expandable and contractible in a longitudinal direction.

### (Supplementary Note 3)

The quantum device according to Supplementary Note 1 or 2, in which
the socket is placed on the interposer.

### (Supplementary Note 4)

The quantum device according to any one of Supplementary Notes 1 to 3, in which
at least one of the interposer or the socket is in contact with a cooling unit having a cooling function.

### (Supplementary Note 5)

The quantum device according to any one of Supplementary Notes 1 to 4, in which
the socket has a facing surface facing the first wiring layer,
the socket further includes a connection unit configured to connect the facing surface and the first metal surface, and
the connection unit has a second metal surface.

### (Supplementary Note 6)

The quantum device according to Supplementary Note 5, in which
the connection unit covers the facing surface.

### (Supplementary Note 7)

The quantum device according to any one of Supplementary Notes 1 to 6, in which
the interposer includes the first wiring layer on a surface of the interposer, and
the first wiring layer contains an alloy having superconductivity.

### (Supplementary Note 8)

The quantum device according to Supplementary Note 7, in which
the first metal surface includes a superconducting material.

### (Supplementary Note 9)

The quantum device according to any one of Supplementary Notes 1 to 8, in which
a gap is provided between the quantum chip and the recessed unit.

### (Supplementary Note 10)

A method for manufacturing a quantum device, the method including:
mounting a quantum chip over a first wiring layer of an interposer; and
disposing a socket including a plurality of terminals to face the first wiring layer, in which
in the disposing, a board having a second wiring layer is disposed to face the first wiring layer,
in the disposing, each of the plurality of terminals electrically connects the first wiring layer and the second wiring layer,
the socket includes a recessed unit housing the quantum chip, and
the recessed unit has a first metal surface covering at least a part of the quantum chip.

1. A quantum device comprising:
a quantum chip;
an interposer including a first wiring layer over which the quantum chip is mounted;
a socket disposed to face the first wiring layer and including a plurality of terminals; and
a board having a second wiring layer facing the first wiring layer, wherein
each of the plurality of terminals electrically connects the first wiring layer and the second wiring layer,
the socket includes a recessed unit housing the quantum chip, and
the recessed unit has a first metal surface covering at least a part of the quantum chip.

2. The quantum device according to claim 1, wherein
each of the plurality of terminals is a pin, and
the pin is expandable and contractible in a longitudinal direction.

3. The quantum device according to claim 1, wherein
the socket is placed on the interposer.

4. The quantum device according to claim 3, wherein
at least one of the interposer or the socket is in contact with a cooling unit having a cooling function.

5. The quantum device according to claim 1, wherein
the socket has a facing surface facing the first wiring layer,
the socket further includes a connection unit configured to connect the facing surface and the first metal surface, and
the connection unit has a second metal surface.

6. The quantum device according to claim 5, wherein
the connection unit covers the facing surface.

7. The quantum device according to claim 1, wherein
the interposer includes the first wiring layer on a surface of the interposer, and
the first wiring layer contains an alloy having superconductivity.

8. The quantum device according to claim 7, wherein
the first metal surface includes a superconducting material.

9. The quantum device according to claim 1, wherein
a gap is provided between the quantum chip and the recessed unit.

10. A method for manufacturing a quantum device, the method comprising:
mounting a quantum chip over a first wiring layer of an interposer; and
disposing a socket including a plurality of terminals to face the first wiring layer, wherein
in the disposing, a board having a second wiring layer is disposed to face the first wiring layer,
in the disposing, each of the plurality of terminals electrically connects the first wiring layer and the second wiring layer,
the socket includes a recessed unit housing the quantum chip, and
the recessed unit has a first metal surface covering at least a part of the quantum chip.
